(19) United States
(12) Patent Application Publication
(10) Pub. No.: US 2025/0072191 A1
(43) Pub. Date: Feb. 27, 2025

(54) LED DRIVING DEVICE, METHOD OF FABRICATING LED DRIVING DEVICE AND DISPLAY DEVICE INCLUDING LED DRIVING DEVICE

(71) Applicant: SAPIEN SEMICONDUCTORS INC., Gyeonggi-do (KR)

(72) Inventors: Kun Ho SONG, Seoul (KR); Myunghee LEE, Seoul (KR)

(73) Assignee: SAPIEN SEMICONDUCTORS INC., Gyeonggi-do (KR)

(21) Appl. No.: 18/798,767

(22) Filed: Aug. 8, 2024

(30) Foreign Application Priority Data
Aug. 22, 2023 (KR) 10-2023-0109504

(51) Int. Cl. H01L 33/62; H01L 25/075; H01L 25/16

(52) U.S. Cl. CPC H01L 33/62; H01L 25/0753; H01L 25/167; H01L 2933/0066

(57) ABSTRACT

Disclosed are an LED driving device, a method of fabricating the LED driving device and a display device including the LED driving device. The LED driving device includes a drive circuit part for driving an LED; an input/output pad for input/output of a driving-related signal of the LED, the input/output pad being connected to the drive circuit part; a wiring part formed based on a metal deposited or plated through a via formed in scribe lanes positioned on at least one side surface of the drive circuit part and configured to connect an attachment part for attachment to the drive circuit part, the input/output pad and a main board; and an insulating film configured to insulate a peripheral region of the drive circuit part except for a region in which the drive circuit part and the input/output pad are connected to the wiring part.

### CROSS-REFERENCE TO RELATED APPLICATION

This application claims priority to Korean Patent Application No. 10-2023-0109504 filed on Aug. 22, 2023 with the Korean Intellectual Property Office, the disclosure of which is incorporated herein by reference.

### TECHNICAL FIELD

The present disclosure relates to a Light-Emitting Diode (LED) driving device, a method of fabricating the LED driving device and a display device including the LED driving device, and more particularly to a technology for fabricating an LED driving device as a drive circuit for mounting a drive circuit (Drive IC) and LED on a main panel by forming a silicon side via to secure an area for mounting the drive circuit and LED on a substrate and forming wiring.

### BACKGROUND

Recently, display devices including Light-Emitting Diodes (LEDs) can be applied to various fields, from small mobile devices to large outdoor displays.

In particular, a display device is being utilized in a wider range of fields, such as various devices of vehicles and Augmented Reality (AR) and Virtual Reality (VR) devices.

Therefore, improvements in various characteristics such as various areas, various shapes, high resolution, process time, manufacturing cost, high reliability, and fast response speed are still required.

In addition, a drive circuit for driving a display is still in need of improvement in various characteristics.

In micro-LED display products which are one type of LEDs, the driving of the display device is controlled using a micro-LED pixel drive circuit that functions as a control driver.

The main features of a micro-LED and a micro-LED pixel drive circuit are, first, that the chip size is extremely small.

Second, since the chip sizes of the micro-LED and micro-LED pixel driver circuit are extremely small compared to a controller, MPU, and memory, an existing packaging method of processing an existing wafer cannot be applied.

When the existing process is applied, productivity is very low, and yield loss and quality/reliability problems occur.

To mount a pixel circuit (Pixel IC) suitable for a high resolution, existing chip mounting or pick & place cannot be applied, so the mass polydimethylsiloxane (PDMS; silicone) stamp transfer or the laser transfer method should be applied.

There is a need to develop a key package mounting process as a low-cost mass production solution for applying micro-LED driver circuit wafers to display products.

### BRIEF SUMMARY

Therefore, the present disclosure has been made in view of the above problems, and it is one of the objects of the present disclosure to provide a Light-Emitting Diode (LED) driving device as a drive circuit for mounting a drive circuit (Drive IC) and LED on a main panel by forming a silicon side via to secure an area for mounting the drive circuit and LED on a substrate and forming wiring; a method of fabricating the LED driving device; and a display device including the LED driving device.

It is another object of the present disclosure to provide an LED driving device applicable to a side Through Silicon Via (TSV) for 3D micro-LEDs and micropixel driving circuits, a method of fabricating the LED driving device, and a display device including the LED driving device.

It is still another object of the present disclosure to provide an LED driving device capable of implementing a high-resolution display device with reduced cost, area and size by applying a side Through Silicon Via (TSV) for 3D micro-LEDs and micropixel driving circuits.

It is still another object of the present disclosure to improve assembly efficiency and simplify the fabrication process by forming a via in scribe lanes of a wafer for electrical connection between an LED and a drive circuit.

It is yet another object of the present disclosure to fabricate an LED driving device as a circuit (Integrated Circuit, IC) wafer by applying a side Through Silicon Via (TSV) to scribe lanes and, thus, using a relatively inexpensive bulk wafer without using a Silicon On Insulator (SOI) wafer.

In accordance with an aspect of the present disclosure, the above and other objects can be accomplished by the provision of a Light Emitting Diode (LED) driving device, including: a drive circuit part for driving an LED; an input/output pad for input/output of a driving-related signal of the LED, the input/output pad being connected to the drive circuit part; a wiring part formed based on a metal deposited or plated through a via formed in scribe lanes positioned on at least one side surface of the drive circuit part and configured to connect an attachment part for attachment to the drive circuit part, the input/output pad and a main board; and an insulating film configured to insulate a peripheral region of the drive circuit part except for a region in which the drive circuit part and the input/output pad are connected to the wiring part.

After the input/output pad is positioned on the drive circuit part to form one chip, and the scribe lanes are positioned on at least one side surface of the chip so that a metal is plated or deposited through the via generated in opposite sides based on the drive circuit part in the scribe lanes divided by the scribe lanes, the plated or deposited metal may form rewiring thought pattern-etching so that the wiring part connects an attachment part for attachment of the drive circuit part and the input/output pad to a main board.

The attachment part may be positioned on an opposite side of a part where the input/output pad is positioned, and attached in at least one form of plating, a bump, and a solder ball.

After the scribe lanes are cut from at least one side surface of the drive circuit part, at least one side surface of the drive circuit part may be deposited or plated with the metal, so that the wiring part is interconnected to an attachment part for attachment of the input/output pad to a main board.

In accordance with another aspect of the present disclosure, there is provided a method of fabricating the LED driving device, the method including: positioning an input/output pad on a drive circuit part to form one chip, and positioning scribe lanes on at least one side surface of the chip to prepare a wafer divided by the scribe lanes; forming rewiring by forming a via in the scribe lanes, generating an insulating film, depositing or plating a metal on the insulating film, and pattern-etching the deposited or plated metal and the scribe lanes; forming a wiring part in which the rewiring, formed as an opposite side of the wafer is polished (ground), the metal is deposited or plated, and then a rewiring pad pattern is formed, is connected to the rewiring pad pattern; attaching an attachment part for attachment of a main board to the rewiring pad pattern; and dividing the wafer based on the chip to form an LED driving device.

The forming of the rewiring may include: removing a tag metal from the scribe lanes and forming the via to have a diameter of 2 um to 60 um; forming the insulating film of 0.5 um to 5 um on the drive circuit part, the input/output pad and the via; etching opposite sides of the input/output pad to be opened; pad-masking the input/output pad, and forming a barrier film on the insulating film to prevent migration of metal; depositing or applying the metal to form a metal layer to cover the barrier film; and pattern-etching the metal layer to form rewiring.

The forming of the wiring part may include: rotating the wafer to an opposite side, and polishing the opposite side of the wafer to a position of the formed rewiring; forming an insulating film and barrier film on the polished surface, and depositing a metal seed to plate with the metal; and forming a wiring part in which the rewiring, formed as the rewiring pad pattern is formed by plating the plated metal with a metal and removing a metal film of the scribe lanes, is connected to the rewiring pad pattern.

The scribe lanes may include Si, the insulating film may include SiO₂, the barrier film may include at least one of Ti, TiN, Ta and TaN, and the metal may include at least one of Cu and W.

The attachment part may be positioned on an opposite side of a part where the input/output pad is positioned, and attached in at least one form of plating, a bump, and a solder ball.

In accordance with yet another aspect of the present disclosure, there is provided a display device, including a Light Emitting Diode (LED) and an LED driving device, wherein the LED driving device includes a drive circuit part for driving an LED; an input/output pad for input/output of a driving-related signal of the LED, the input/output pad being connected to the drive circuit part; a wiring part formed based on a metal deposited or plated through a via formed in scribe lanes positioned on at least one side surface of the drive circuit part and configured to connect an attachment part for attachment to the drive circuit part, the input/output pad and a main board; and an insulating film configured to insulate a peripheral region of the drive circuit part except for a region in which the drive circuit part and the input/output pad are connected to the wiring part.

After the input/output pad is positioned on the drive circuit part to form one chip, and the scribe lanes are positioned on at least one side surface of the chip so that a metal is deposited or plated through the via generated in opposite sides based on the drive circuit part in the scribe lanes of the wafer divided by the scribe lanes, the deposited or plated metal may form rewiring thought pattern-etching so that the wiring part connects an attachment part for attachment of the drive circuit part and the input/output pad to a main board.

The LED and the LED driving device may have a same size and are bonded to each other by wafer-to-wafer bonding, or may be bonded by chip-to-wafer bonding on the LED driving device by stamping or laser transfer and mounted on the main panel.

After the scribe lanes are cut from at least one side surface of the drive circuit part, at least one side surface of the drive circuit part may be deposited or plated with the metal, so that the wiring part is interconnected to an attachment part for attachment of the input/output pad to a main board.

### BRIEF DESCRIPTION OF THE DRAWINGS

The above and other objects, features and other advantages of the present disclosure will be more clearly understood from the following detailed description taken in conjunction with the accompanying drawings, in which:

FIGS. 1A to 2F illustrate the structural change of a Light-Emitting Diode (LED) driving device fabricated using a method of fabricating the LED driving device according to an embodiment of the present disclosure;

FIG. 3 illustrates the structure of an LED driving device according to an embodiment of the present disclosure;

FIGS. 4A and 4B illustrate a 3D micro-LED pixel structure according to an embodiment of the present disclosure;

FIGS. 5A to 5C illustrate a 3D micro-LED pixel structure based on side via surface plating according to an embodiment of the present disclosure;

FIG. 6 illustrates the interposer-applied structure of an LED driving device for a large display according to an embodiment of the present disclosure; and

FIG. 7 illustrates a method of fabricating the LED driving device according to an embodiment of the present disclosure.

### DETAILED DESCRIPTION

Specific structural and functional descriptions of embodiments according to the concept of the present disclosure disclosed herein are merely illustrative for the purpose of explaining the embodiments according to the concept of the present disclosure. Furthermore, the embodiments according to the concept of the present disclosure can be implemented in various forms and the present disclosure is not limited to the embodiments described herein.

The embodiments according to the concept of the present disclosure may be implemented in various forms as various modifications may be made. The embodiments will be described in detail herein with reference to the drawings. However, it should be understood that the present disclosure is not limited to the embodiments according to the concept of the present disclosure, but includes changes, equivalents, or alternatives falling within the spirit and scope of the present disclosure.

The terms such as “first” and “second” are used herein merely to describe a variety of constituent elements, but the constituent elements are not limited by the terms. The terms are used only for the purpose of distinguishing one constituent element from another constituent element. For example, a first element may be termed a second element and a second element may be termed a first element without departing from the scope of rights according to the concept of the present disclosure.

It will be understood that when an element is referred to as being “on”, “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Other words used to describe the relationship between elements should be interpreted in a like fashion (e.g., “between,” versus “directly between,” “adjacent,” versus “directly adjacent,” etc.).

The terms used in the present specification are used to explain a specific exemplary embodiment and not to limit the present inventive concept. Thus, the expression of singularity in the present specification includes the expression of plurality unless clearly specified otherwise in context. Also, terms such as “include” or “comprise” in the specification should be construed as denoting that a certain characteristic, number, step, operation, constituent element, component or a combination thereof exists and not as excluding the existence of or a possibility of an addition of one or more other characteristics, numbers, steps, operations, constituent elements, components or combinations thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present disclosure will now be described more fully with reference to the accompanying drawings, in which exemplary embodiments of the disclosure are shown. This disclosure may, however, be embodied in many different forms and should not be construed as limited to the exemplary embodiments set forth herein. Like reference numerals in the drawings denote like elements.

On a single semiconductor wafer, numerous semiconductor chips with integrated electronic circuits are formed on small square dies, and scribe lanes or scribe lines are formed to ensure free space between the semiconductor chips, i.e., between dies. Therefore, after wafer processing is completed, individual semiconductor chips can be divided by scribe lanes and cut one by one based on the scribe lanes. Hereinafter, an embodiment of forming a side via for electrical connection between semiconductor devices by utilizing scribe lanes for distinguishing semiconductor chips is described.

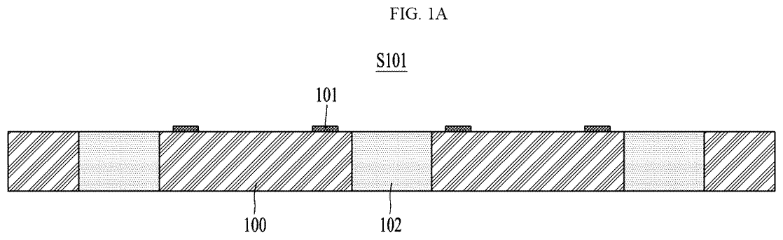

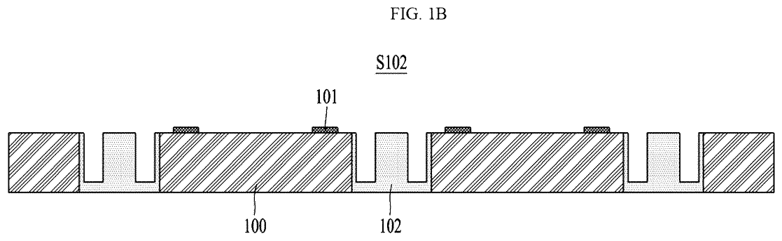

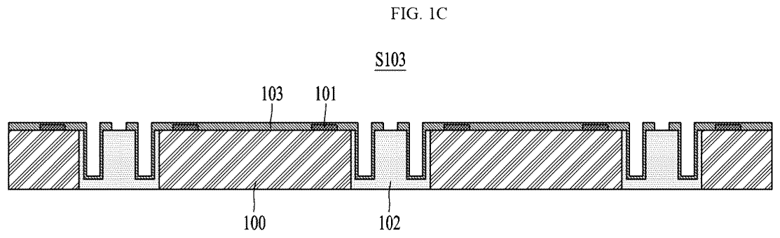

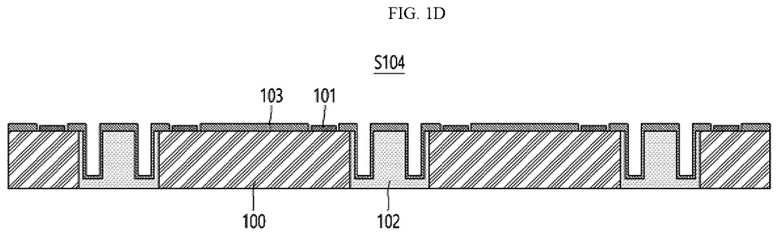

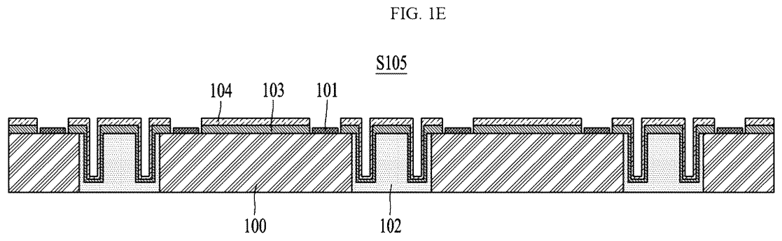

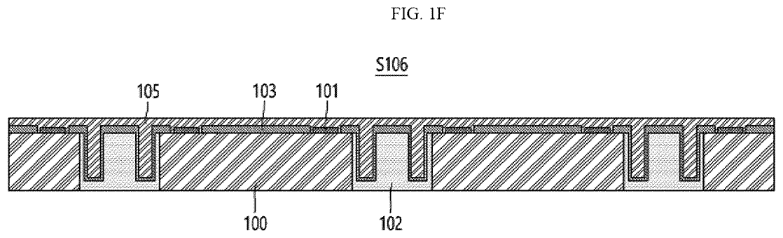

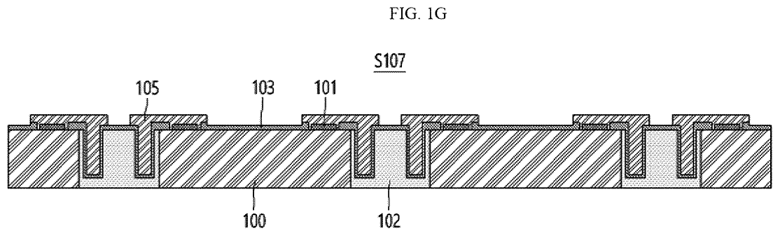

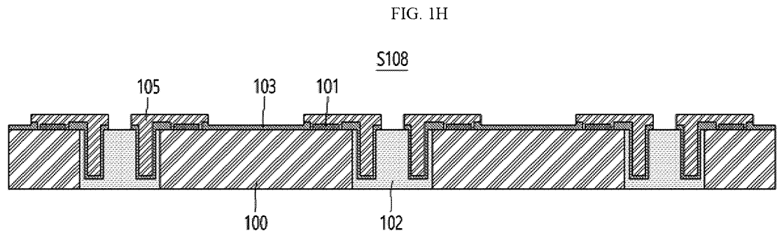

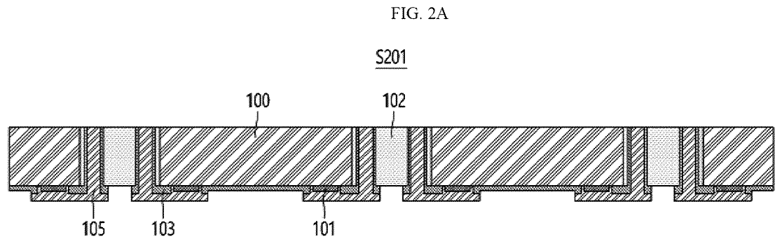

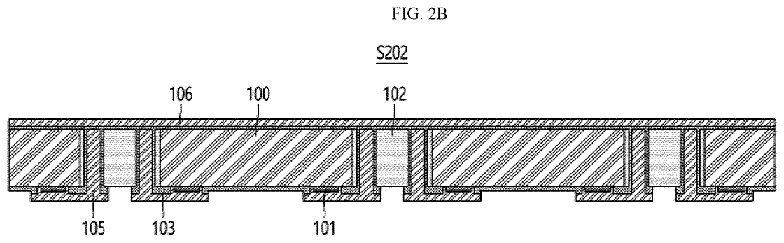

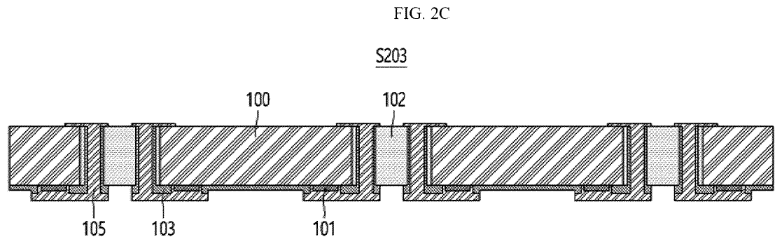

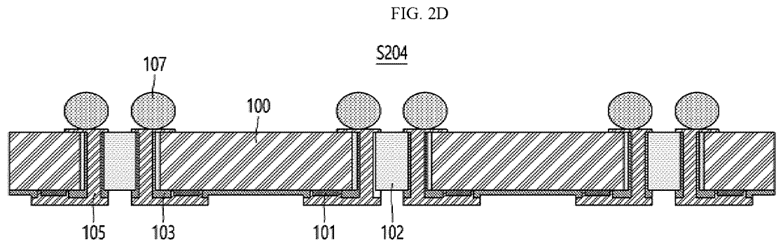

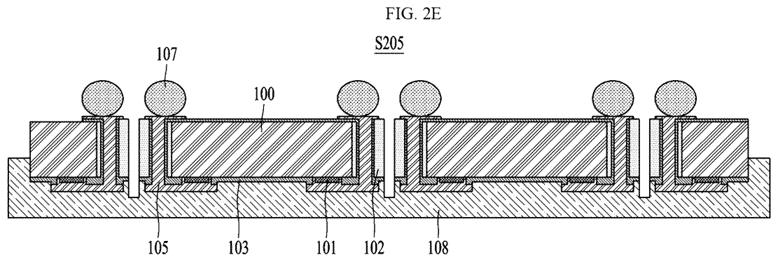

FIGS. 1A to 2F are drawings explaining the structural change of a Light-Emitting Diode (LED) driving device fabricated using a method of fabricating the LED driving device according to an embodiment of the present disclosure.

FIGS. 1A to 1H illustrate a wafer front-side process procedure in the structure of an LED driving device manufactured using the method of fabricating the LED driving device according to an embodiment of the present disclosure, and FIGS. 2A to 2F illustrate a wafer back-side process procedure in the structure of the LED driving device manufactured using the method of fabricating the LED driving device according to an embodiment of the present disclosure.

FIG. 1A illustrates a wafer of a drive circuit part in the structural change of the LED driving device manufactured using the method of fabricating the LED driving device according to an embodiment of the present disclosure.

Referring to FIG. 1A, in step S101 of the method of fabricating the LED driving device according to an embodiment of the present disclosure, an input/output pad 101 is located on a drive circuit part 100 to form one chip, and a scribe lane 102 is located on a side surface surrounding the chip, thereby preparing a wafer whose chips are separated by the scribe lane 102. For example, the surrounding side surface is at least one, preferably four.

In the structural change of the LED driving device manufactured using the method of fabricating the LED driving device according to an embodiment of the present disclosure, FIG. 1B illustrates a structural change according to a procedure of forming a via in the scribe lane 102.

Referring to FIG. 1B, in step S102 of the method of fabricating the LED driving device according to an embodiment of the present disclosure, a via is formed in the scribe lane 102.

That is, the method of fabricating the LED driving device according to an embodiment of the present disclosure removes a tag metal in the scribe lane 102 and forms a via with a diameter of 2 um to 60 um.

The method of fabricating the LED driving device according to an embodiment of the present disclosure may form a via according to the performance of Deep REACTIVE ION ETCHER (DRIE) or Inductively Coupled Plasma Reactive Ion Etcher (ICP-RIE).

In the structural change of the LED driving device manufactured using the method of fabricating the LED driving device according to an embodiment of the present disclosure, FIG. 1C illustrates a structural change according to a procedure of forming an insulating film.

Referring to FIG. 1C, an insulating film 103 is formed in step S103 of the method of fabricating the LED driving device according to an embodiment of the present disclosure.

By the method of fabricating the LED driving device according to an embodiment of the present disclosure, an insulating film 103 of 0.5 um to 5 um is formed on the input/output pad 101 and the via.

In the structural change of the LED driving device manufactured using the method of fabricating the LED driving device according to an embodiment of the present disclosure, FIG. 1D illustrates a structural change according to an open procedure of etching the insulating film.

Referring to FIG. 1D, the insulating film 103 portions on both sides of the input/output pad 101 are etched to be opened in step S104 of the method of fabricating the LED driving device according to an embodiment of the present disclosure.

In the structural change of the LED driving device manufactured using the method of fabricating the LED driving device according to an embodiment of the present disclosure, FIG. 1E illustrates a structural change according to a procedure of forming a barrier film.

Referring to FIG. 1E, a barrier film 104 for preventing migration of metal is formed on the insulating film 103 after pad masking for the input/output pad 101 in step S105 of the method of fabricating the LED driving device according to an embodiment of the present disclosure. The barrier film 104 is omitted for convenience in the drawings hereafter, but exists.

In the structural change of the LED driving device manufactured using the method of fabricating the LED driving device according to an embodiment of the present disclosure, FIG. 1F illustrates a structural change according to metal deposition or a plating procedure.

Referring to FIG. 1F, the metal 105 is deposited or plated on the insulating film 103 using a sputtering process to cover the barrier film 104 in step S106 of the method of fabricating the LED driving device according to an embodiment of the present disclosure.

For example, the barrier film 104 may include at least one of Ti, TIN, Ta and TaN and may be formed to a thickness of preferably 30 to 50 nm.

In the structural change of the LED driving device manufactured using the method of fabricating the LED driving device according to an embodiment of the present disclosure, FIG. 1G illustrates a structural change according to a rewiring formation procedure of using metal pattern etching.

Referring to FIG. 1G, the deposited or plated metal is pattern-etched to form rewiring 105 in step S107 of the method of fabricating the LED driving device according to an embodiment of the present disclosure. By this rewiring step, the input/output pad 101 is connected to the via formed on the side, thereby forming an electrical contact point on the back surface of the wafer.

In the structural change of the LED driving device manufactured using the method of fabricating the LED driving device according to an embodiment of the present disclosure, FIG. 1H illustrates a structural change according to a rewiring formation procedure of pattern-etching the scribe lanes.

Referring to FIG. 1H, the scribe lane 102 is pattern-etched to form rewiring 105 in step S108 of the method of fabricating the LED driving device according to an embodiment of the present disclosure. That is, an insulating film formed on the scribe lane 102 may be removed through pattern-etching.

In the structural change of the LED driving device manufactured using the method of fabricating the LED driving device according to an embodiment of the present disclosure, FIG. 2A illustrates a structural change according to a grinding procedure for the back surface of the wafer. Referring to FIG. 2A, in step S201 of the method of fabricating the LED driving device according to an embodiment of the present disclosure, the wafer that has been subjected to step S108 is rotated to expose the opposite side thereof, and the opposite side of the wafer is polished until the rewiring 105 is exposed.

In the structural change of the LED driving device manufactured using the method of fabricating the LED driving device according to an embodiment of the present disclosure, FIG. 2B illustrates a structural change according to insulating film formation, barrier deposition and metal seed deposition procedures.

Referring to FIG. 2B, in step S202 of the method of fabricating the LED driving device according to an embodiment of the present disclosure, an insulating film and a barrier film are formed on the polished surface, and then a metal seed is deposited to deposit and plate a metal 106. Additionally, the insulating film, barrier film formation, and metal deposition/plating processes have been described above with reference to FIGS. 1A to 1H, so detailed descriptions thereof are omitted.

In the structural change of the LED driving device manufactured using the method of fabricating the LED driving device according to an embodiment of the present disclosure, FIG. 2C illustrates a structural change according to a rewiring pad pattern formation procedure.

Referring to FIG. 2C, in step S203 of the method of fabricating the LED driving device according to an embodiment of the present disclosure, a wiring part 105 in which the formed rewiring and the rewiring pad pattern are connected to each other is formed as a rewiring pad pattern is formed by plating the metal and removing the metal films of scribe lanes for the deposited or plated the metal 106.

In the structural change of the LED driving device manufactured using the method of fabricating the LED driving device according to an embodiment of the present disclosure, FIG. 2D illustrates a structural change according to a board-mounting pad solder ball attachment procedure.

Referring to FIG. 2D, an attachment part 107 for attachment to a main board is attached to the rewiring pad pattern in step S204 of the method of fabricating the LED driving device according to an embodiment of the present disclosure.

In the structural change of the LED driving device manufactured using the method of fabricating the LED driving device according to an embodiment of the present disclosure, FIG. 2E illustrates a structural change according to a chip sawing procedure.

Referring to FIG. 2E, a sawing tape 108 is attached to the wafer to divide it based on one chip in step S205 of the method of fabricating the LED driving device according to an embodiment of the present disclosure.

In the structural change of the LED driving device manufactured using the method of fabricating the LED driving device according to an embodiment of the present disclosure, FIG. 2F illustrates a structural change according to a procedure of completing an LED driving device.

Referring to FIG. 2F, an LED driving device is completed as a side TSV Via CSP (chip scale package) in step S206 of the method of fabricating the LED driving device according to an embodiment of the present disclosure.

That is, the method of fabricating the LED driving device according to an embodiment of the present disclosure divides the wafer based on one chip to form an LED driving device. Accordingly, the present disclosure can provide an LED driving device for implementing a high-resolution display device with reduced cost, area, and size through the application of a side TSV (Through Silicon Via) for a 3D micro-LED and micropixel driving circuit.

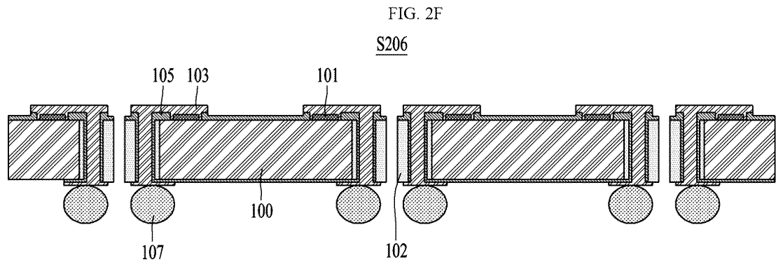

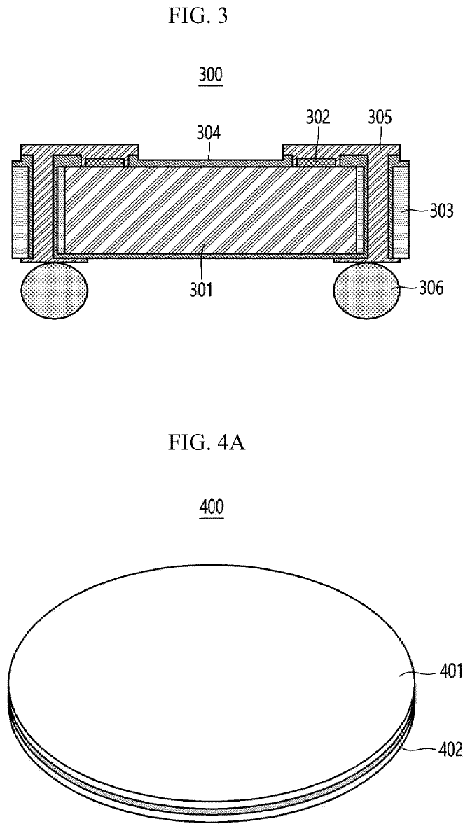

FIG. 3 illustrates the structure of an LED driving device according to an embodiment of the present disclosure.

FIG. 3 illustrates the configuration and structure of the LED driving device according to an embodiment of the present disclosure.

Referring to FIG. 3, an LED driving device 300 according to an embodiment of the present disclosure may be formed based on a technology that allows a via to be formed on the side of a chip (i.e., a scribe lane) rather than the center of the chip.

The LED driving device 300 according to an embodiment of the present disclosure may include a drive circuit part 301, an input/output pad 302, a scribe lane 303, an insulating film 304, a barrier film (not shown), a wiring part 305 and an attachment part 306.

The drive circuit part 301 according to an embodiment of the present disclosure may be connected to a main board and an LED to drive the LED.

For example, an LED may be referred to as any one of a micro-LED, a light-emitting device, a pixel device, and an LED chip.

For example, the input/output pad 302 may be connected to the drive circuit part 301, and for input/output related to driving an LED, may process input/output.

The input/output pad 302 is a contact point connected to the drive circuit part 301, and LED is connected to the drive circuit part 301.

The LED driving device 300 inputs signals, such as driving voltage and grayscale data for LED light emission, to the drive circuit part 301 through the input/output pad 302.

The drive circuit part 301 generates an LED driving signal such as Pulse Width Modulation (PWM), and then transmits the driving signal to the LED through the input/output pad 302 to make the LED light up.

Here, the signal that has been input to the drive circuit part 301 may be input from an external main board/host (not shown) connected to the attachment part 306 through a side via. Next, the drive circuit part 301 may generate a PWM signal for driving the LED and transmit the PWM signal to the LED through another input/output pad 302.

The insulating film 304 according to an embodiment of the present disclosure may insulate the peripheral region of the drive circuit part 301 except for an area where the drive circuit part 301 and the input/output pad 302 are connected to the wiring part 305.

The wiring part 305 according to an embodiment of the present disclosure may be formed based on the metal deposited or plated through a via formed in the scribe lane 303 located on at least one side surface surrounding the drive circuit part 301.

In addition, the wiring part 305 may connect the drive circuit part 301 and the input/output pad 302 to the attachment part 306 for attaching a main board.

The input/output pad 302 is located on the drive circuit part 301 to form one chip, the scribe lane 303 is located on at least one side surface of the chip, the scribe lane 303 of the wafer divided by the scribe lane 303 is deposited or plated with a metal through a via formed on the opposite sides based on the drive circuit part 301, and then the deposited or plated metal is rewired through pattern-etching, so that the wiring part 305 according to an embodiment of the present disclosure may connect the drive circuit part 301 and the input/output pad 302 to the attachment part 306 for attaching a main board.

According to an embodiment of the present disclosure, the attachment part 306 may be positioned on an opposite side where the input/output pad 302 is positioned, and may be formed in a form in which a solder ball is attached.

That is, the attachment part 306 may be positioned on an opposite side where the input/output pad 302 is positioned, and the input/output pad 302 may be plated with at least one metal of SnAgCu, Sn, Au and AuSn, or one of a bump and solder ball based on at least one metal of a Cu pillar, Cu, Au and AuSn may be attached to the input/output pad 302.

For example, the scribe lane 303 may include Si, the insulating film 304 may include SiO₂, and the metal forming the wiring part 305 may include at least one of Cu and W.

Accordingly, the present disclosure can provide an LED driving device as a drive circuit for mounting a drive circuit (Drive IC) and LED on a main panel by forming a silicon side via to secure an area for mounting the drive circuit and LED on a substrate and forming wiring, a method of fabricating the LED driving device, and a display device including the LED driving device.

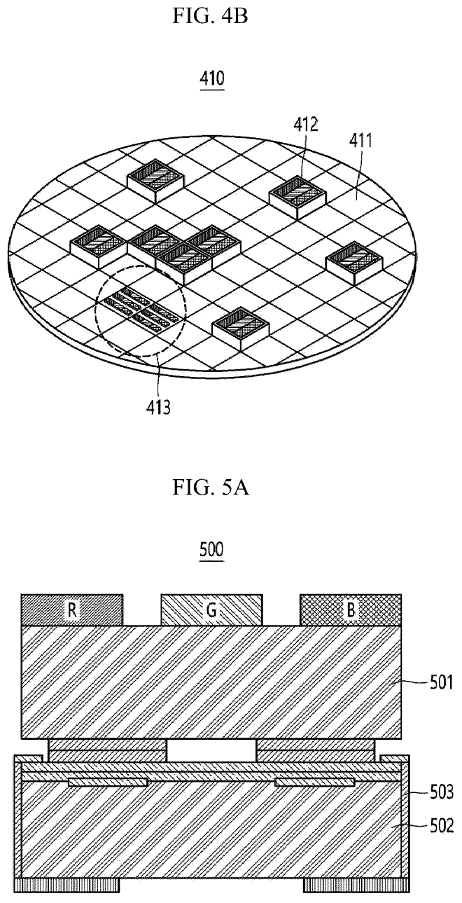

FIGS. 4A and 4B illustrate a 3D micro-LED pixel structure according to an embodiment of the present disclosure.

FIG. 4A illustrates a one-to-one wafer-to-wafer bonding structure applied to a 3D micro-LED pixel structure according to an embodiment of the present disclosure.

Referring to FIG. 4A, a 3D micro-LED pixel structure 400 according to an embodiment of the present disclosure has a structure wherein an LED 401 and an LED driving device 402 are bonded to each other in the form of wafer-to-wafer.

The wafer sizes of the LED 401 and the LED driving device 402 are the same at 1:1, and the input/output pads on the LED 401 and the LED driving device 402 are electrically interconnected by direct metal-to-metal bonding.

After wafer bonding is performed, the LED driving device 402 is mounted on the main panel, a hole is drilled in the silicon for electrical connection, metal is filled by the Through Silicon Via (TSV) method to create wiring, and an input/output pad is formed on the mounting surface to connect to the main panel.

FIG. 4B illustrates a multi-to-one wafer-to-wafer bonding structure applied to the 3D micro-LED pixel structure according to an embodiment of the present disclosure.

Referring to FIG. 4B, a 3D micro-LED pixel structure 410 according to an embodiment of the present disclosure has a structure wherein each LED device 411 is a wafer and each LED driving device 412 is bonded thereto in the form of wafer-to-wafer.

When micro-LED R, G and B devices are respectively different wafers 411, a chip and a wafer are bonded onto the surface of the LED driving device 412 by a stamp or laser transfer method as described below.

For example, a plurality of micro-LEDs 413, in addition to pixels corresponding to micro-LED R, G and B devices, may be attached onto a wafer corresponding to the LED driving device 412.

That is, if a plurality of LED driving devices 412 can be implemented in a single circuit, the micro-LEDs 413 may be attached onto the wafers of the LED driving devices 412. Next, the bonding wafer chip is separated by laser sawing or plasma sawing and mounted in the main panel.

Laser sawing is a full-cutting method that cuts the scribe lanes of a wafer to increase productivity in the case of small chips.

Plasma sawing can reduce the width of a scribe lane to 40 um to 50 um or less at the maximum, and can separate chips within a wafer in a short time.

For example, the 3D micro-LED pixel structure 400 and the 3D micro-LED pixel structure 410 may be included in a display device.

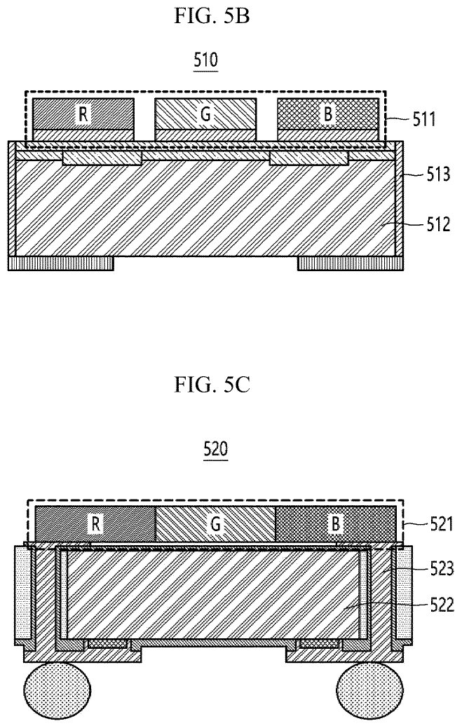

FIGS. 5A to 5C illustrate a 3D micro-LED pixel structure based on side via surface plating according to an embodiment of the present disclosure.

FIG. 5A illustrates the 3D micro-LED pixel structure of the side via surface plating-based 3D micro-LED pixel structure according to an embodiment of the present disclosure which is related to the 3D micro-LED pixel structure 400 of FIG. 4A.

Referring to FIG. 5A, an embodiment to which a method of forming silicon side vias in relation to input/output formation with TSV in a 3D micro-LED pixel structure 500 according to an embodiment of the present disclosure and interconnecting the silicon side vias by plating the side surfaces of the side vias without filling the vias with a metal such as copper is applied is illustrated.

For example, a 3D micro-LED pixel structure 500 includes an LED 501 and an LED driving device 502, and a silicon side via 503 is formed on side surfaces of the LED driving device 502 of the 3D micro-LED pixel structure 500.

The input/output pads of the LED 501 and LED driving device 502 may be interconnected, and the silicon side via 503 connected to the input/output pads may be connected to an attachment part.

FIG. 5B illustrates the 3D micro-LED pixel structure of the side via surface plating-based 3D micro-LED pixel structure according to an embodiment of the present disclosure which is related to the 3D micro-LED pixel structure 410 of FIG. 4B.

In relation to the input/output formation with TSV in the 3D micro-LED pixel structure 510 according to an embodiment of the present disclosure, FIG. 5B illustrates a structure to which a method of forming a silicon side via and, instead of filling the via with plating, plating side via surfaces to be interconnected is applied.

For example, in a 3D micro-LED pixel structure 510, each of an LED device 511 and LED driving device 512 forming the LED is a wafer, and a silicon side via 513 is formed on side surfaces of the LED driving device 512.

Input/output pads of the LED device 511 and LED driving device 512 may be interconnected, and the silicon side via 513 connected to the input/output pads may be connected to an attachment part.

FIG. 5C illustrates the 3D micro-LED pixel structure of the side via surface plating-based 3D micro-LED pixel structure according to an embodiment of the present disclosure which is an upside-down inversion of the LED driving device illustrated in FIG. 3.

Referring to FIG. 5C, a 3D micro-LED pixel structure 520 according to an embodiment of the present disclosure may be fabricated by attaching an LED 521, composed of micro-LEDs, to the opposite surface of a wafer in which a silicon side via 523 has been formed, and an input signal terminal may be formed thereon.

The input signal terminal may be connected to an LED driving device 522 through the silicon side via 523.

For example, the 3D micro-LED pixel structure 500, the 3D micro-LED pixel structure 510 and the 3D micro-LED pixel structure 520 may be included in a display device.

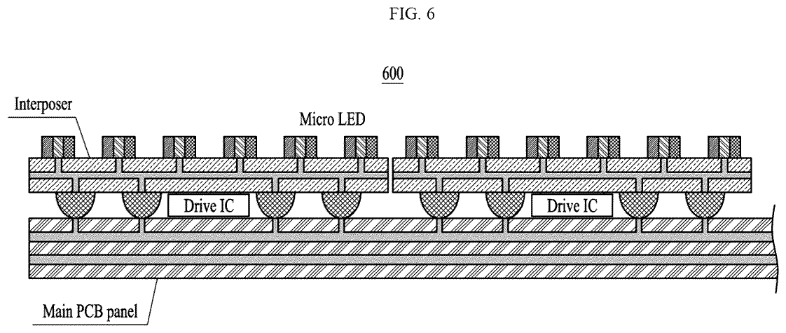

FIG. 6 illustrates the interposer-applied structure of an LED driving device for a large display according to an embodiment of the present disclosure.

FIG. 6 is a drawing for explaining the interposer-applied structure of an LED driving device for a large display according to an embodiment of the present disclosure.

FIG. 6 illustrates a structure 600 wherein an LED driving device is formed as a pixel driving circuit (micro pixel driving IC, MPD) on an interposer electrically connected to a display substrate through a plurality of bumps.

For example, the interposer may be one of a film interposer, a glass interposer and a silicon interposer. In addition, the interposer may be formed based on a reel-to-reel process.

The plural bumps may include a column bump, a low bump and a voltage bump.

More specifically, eight bumps, i.e., a first column bump (Col 1), a second column bump (Col 2), a first low bump (Row 1), a second low bump (Row 2), a VCC voltage bump (VCC), a VDD voltage bump (VDD), a reference voltage bump (VREF) and a ground bump (GND), may be formed on a lower surface of the interposer, without being limited thereto, and the configuration of the bumps may be easily changed according to the design. For example, the interposer may include only one column bump and one low bump.

For example, the plural bumps may include at least one metal material of gold (Au) and copper (Cu), without being limited thereto, and known metal materials constituting bumps may be applied.

More specifically, the plural bumps may be at least one type of SnAgCu solder bumps having a pitch of 40 um to 500 um, Cu pillar bumps, Au stud bumps having a pitch of 5 um to 200 um and micro-bumps having a pitch of 5 um to 200 um.

For example, the plural bumps may further include magnetic nanopowder. Thereby, the plural bumps may be controlled to be self-aligned and placed in a correct position during the interposer-forming process.

For example, an LED driving device may be referred to as a drive circuit (Drive IC).

The structure 600 may be formed in the order of a main panel (main PCB panel), an LED driving device, an interposer, and an LED.

The LED driving device may include a row terminal connected to a row line of a row driving circuit among the plural bumps; and a column terminal connected to a column line of a column driving circuit among the plural bumps.

In addition, the LED driving device may include a common device sharing at least one of the row terminal and the column terminal for L (L is a positive integer greater than or equal to 2) display pixels formed on the interposer; and L pixel individual devices connected to the common device and configured to drive the plural light-emitting devices R, G and B included in each of the L display pixels.

For example, the LED driving device may include a first column terminal, second column terminal, first row terminal, second row terminal, VCC voltage terminal, VDD voltage terminal, reference voltage terminal and ground terminal respectively connected to the eight bumps through the via formed inside the interposer, but the present disclosure is not limited thereto.

In addition, the LED driving device may further include a plurality of terminals respectively connected to the plural light-emitting devices R, G and B included in each of the display pixels.

The LED driving device may further include at least one sensor disposed in a sensor region formed on the interposer. For example, the at least one sensor may be a touch sensor, but the present disclosure is not limited thereto.

The common device may include at least one of a power generator configured to generate the power required for a pixel driving circuit; a column signal distributor configured to distribute signals input through the column terminal to L pixel individual devices; and a low signal distributor configured to distribute signals input through a row terminal to L pixel individual devices.

In addition, each of the L pixel individual devices may include a pixel built-in memory configured to store video data input through the column signal distributor.

Meanwhile, sub-pixel regions where multiple light-emitting devices of each of the L display pixels are arranged may be formed at the corners or periphery of the display pixels to be adjacent to each other.

The LED driving device may be arranged on the same surface (upper surface) as the L pixel individual elements of the interposer, but is not limited thereto and may be arranged on different surfaces.

Specifically, the LED driving device may be disposed on the lower surface (i.e., the back surface) of the interposer, and the L pixel individual devices may be formed on the upper surface of the interposer, thereby minimizing damage to the device or chip due to electrostatic discharge (ESD).

More specifically, when the LED driving device is disposed on the lower surface of the interposer, the pixel individual devices may be arranged on the upper surface of the interposer without space constraints even if the number of pixel individual devices is more than 4 (e.g., 6, 8, 16, etc.), thereby securing a space margin and uniformly arranging L pixel individual devices within a pixel cluster.

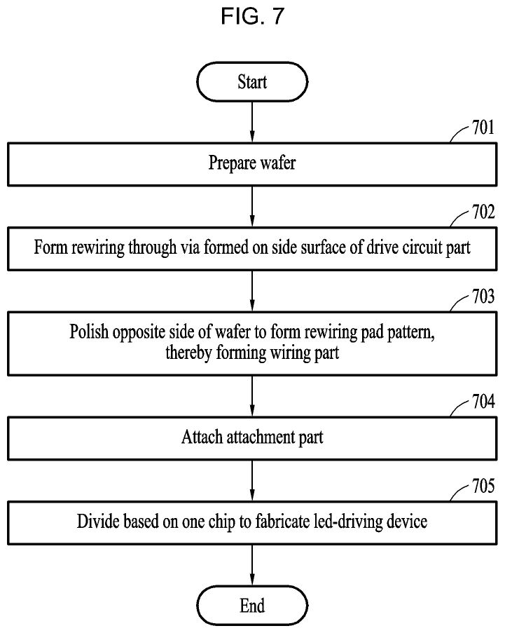

FIG. 7 illustrates a method of fabricating the LED driving device according to an embodiment of the present disclosure.

FIG. 7 illustrates a procedure of forming a via on the side of a chip rather than the center of the chip according to the method of fabricating the LED driving device according to an embodiment of the present disclosure.

Referring to FIG. 7, a wafer is prepared in step 701 of the method of fabricating the LED driving device according to an embodiment of the present disclosure.

That is, according to the method of fabricating the LED driving device according to an embodiment of the present disclosure, an input/output pad is positioned on a drive circuit part to form one chip, and scribe lanes are positioned on at least one side surface of the chip to prepare a wafer divided by scribe lanes.

In step 702 of fabricating the LED driving device according to an embodiment of the present disclosure, rewiring is formed through the via formed on the at least one side surface of the drive circuit part. That is, according to the method of fabricating the LED driving device according to an embodiment of the present disclosure, a via may be formed in scribe lanes, metal is deposited or plated on an insulating film after generating the insulating film, and a metal layer is pattern-etched to form rewiring.

In step 703 of fabricating the LED driving device according to an embodiment of the present disclosure, the opposite side of the wafer is polished to form a rewiring pad pattern, thereby forming a wiring part. That is, the method of fabricating the LED driving device according to an embodiment of the present disclosure may form a wiring part in which the rewiring, formed by forming the rewiring pad pattern after polishing (grinding) the opposite side of the wafer and plating with a metal, and the rewiring pad pattern are connected.

In step 704 of fabricating the LED driving device according to an embodiment of the present disclosure, an attachment part is attached. That is, according to the method of fabricating the LED driving device according to an embodiment of the present disclosure, an attachment part for attaching a main board is attached to the rewiring pad pattern.

In step 705 of the method of fabricating the LED driving device according to an embodiment of the present disclosure, an LED driving device is fabricated by dividing based on one chip.

That is, the method of fabricating the LED driving device according to an embodiment of the present disclosure including dividing the wafer based on one chip to form and fabricate an LED driving device.

Accordingly, the present disclosure can provide an LED driving device applicable to a side Through Silicon Via (TSV) for 3D micro-LEDs and micropixel driving circuits; a method of fabricating the LED driving device, and a display device including the LED driving device.

The present disclosure can provide an LED driving device as a drive circuit for mounting a drive circuit (Drive IC) and LED on a main panel by forming a silicon side via to secure an area for mounting the drive circuit and LED on a substrate and forming wiring; a method of fabricating the LED driving device; and a display device including the LED driving device.

The present disclosure can provide an LED driving device applicable to a side Through Silicon Via (TSV) for 3D micro-LEDs and micropixel driving circuits, a method of fabricating the LED driving device, and a display device including the LED driving device.

The present disclosure can provide an LED driving device capable of implementing a high-resolution display device with reduced cost, area and size by applying a side Through Silicon Via (TSV) for 3D micro-LEDs and micropixel driving circuits.

The present disclosure can fabricate an LED driving device as a circuit (Integrated Circuit, IC) wafer by applying a side Through Silicon Via (TSV) to scribe lanes and, thus, using a relatively inexpensive bulk wafer without using a Silicon On Insulator (SOI) wafer.

Although the present disclosure has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

What is claimed is:

1. A Light Emitting Diode (LED) driving device, comprising:
a drive circuit part for driving an LED;
an input/output pad for input/output of a driving-related signal of the LED, the input/output pad being connected to the drive circuit part;
a wiring part formed based on a metal deposited or plated through a via formed in scribe lanes positioned on at least one side surface of the drive circuit part and configured to connect an attachment part for attachment to the drive circuit part, the input/output pad and a main board; and
an insulating film configured to insulate a peripheral region of the drive circuit part except for a region in which the drive circuit part and the input/output pad are connected to the wiring part.

2. The LED driving device according to claim 1, wherein
after the input/output pad is positioned on the drive circuit part to form one chip, and
the scribe lanes are positioned on at least one side surface of the chip so that a metal is plated or deposited through the via generated in at least one side surface based on the drive circuit part in the scribe lanes divided by the scribe lanes,
the plated or deposited metal forms rewiring thought pattern-etching so that the wiring part connects an attachment part for attachment of the drive circuit part and the input/output pad to a main board.

3. The LED driving device according to claim 1, wherein
the attachment part is positioned on an opposite side of a part where the input/output pad is positioned, and attached in at least one form of plating, a bump, and a solder ball.

4. The LED driving device according to claim 1, wherein
after the scribe lanes are cut from at least one side surface of the drive circuit part,
at least one side surface of the drive circuit part is plated with the metal, so that the wiring part is interconnected to an attachment part for attachment of the input/output pad to a main board.

5. A method of fabricating the LED driving device, the method comprising:
positioning an input/output pad on a drive circuit part to form one chip, and positioning scribe lanes on at least one side surface of the chip to prepare a wafer divided by the scribe lanes;
forming rewiring by forming a via in the scribe lanes, generating an insulating film, depositing or plating a metal on the insulating film, and pattern-etching the plated metal and the scribe lanes;
forming a wiring part in which the rewiring, formed as an opposite side of the wafer is polished (ground), the metal is deposited or plated, and then a rewiring pad pattern is formed, is connected to the rewiring pad pattern;
attaching an attachment part for attachment of a main board to the rewiring pad pattern; and
dividing the wafer based on the chip to form an LED driving device.

6. The method according to claim 5, wherein the forming of the rewiring comprises:
removing a tag metal from the scribe lanes and forming the via to have a diameter of 2 um to 60 um;
forming the insulating film of 0.5 um to 5 um on the drive circuit part, the input/output pad and the via;
etching opposite sides of the input/output pad to be opened;
pad-masking the input/output pad, and forming a barrier film on the insulating film to prevent migration of metal;
depositing or applying the metal to form a metal layer to cover the barrier film; and
pattern-etching the metal layer to form rewiring.

7. The method according to claim 5, wherein the forming of the wiring part comprises:
rotating the wafer to an opposite side, and polishing the opposite side of the wafer to a position of the formed rewiring;
forming an insulating film and barrier film on the polished surface, and depositing a metal seed to plate with the metal; and
forming a wiring part in which the rewiring, formed as the rewiring pad pattern is formed by plating the plated metal with a metal and removing a metal film of the scribe lanes, is connected to the rewiring pad pattern.

8. The method according to claim 7, wherein the scribe lanes comprise Si,
the insulating film comprises SiO₂,
the barrier film comprises at least one of Ti, TiN, Ta and TaN, and
the metal comprises at least one of Cu and W.

9. The method according to claim 5, wherein the attachment part is positioned on an opposite side of a part where the input/output pad is positioned, and attached in at least one form of plating, a bump, and a solder ball.

10. A display device, comprising a Light Emitting Diode (LED) and an LED driving device, wherein
the LED driving device comprises a drive circuit part for driving an LED;
an input/output pad for input/output of a driving-related signal of the LED, the input/output pad being connected to the drive circuit part;
a wiring part formed based on a metal deposited or plated through a via formed in scribe lanes positioned on at least one side surface of the drive circuit part and configured to connect an attachment part for attachment to the drive circuit part, the input/output pad and a main board; and
an insulating film configured to insulate a peripheral region of the drive circuit part except for a region in which the drive circuit part and the input/output pad are connected to the wiring part.

11. The display device according to claim 10, wherein
after the input/output pad is positioned on the drive circuit part to form one chip, and the scribe lanes are positioned on at least one side surface of the chip so that a metal is deposited or plated through the via generated in opposite sides based on the drive circuit part in the scribe lanes of the wafer divided by the scribe lanes,
the deposited or plated metal forms rewiring thought pattern-etching so that the wiring part connects an attachment part for attachment of the drive circuit part and the input/output pad to a main board.

12. The display device according to claim 10, wherein the LED and the LED driving device have a same size and are bonded to each other by wafer-to-wafer bonding, or are bonded by chip-to-wafer bonding on the LED driving device by stamping or laser transfer and mounted on the main panel.

13. The display device according to claim 10, wherein, after the scribe lanes are cut from at least one side surface of the drive circuit part, at least one side surface of the drive circuit part is deposited or plated with the metal, so that the wiring part is interconnected to an attachment part for attachment of the input/output pad to a main board.
